(19) United States
(12) Patent Application Publication
(10) Pub. No.: US 2011/0162698 A1
(43) Pub. Date: Jul. 7, 2011

(54) Solar cells using nanowires and methods of manufacturing the same

(75) Inventors: Xianyu Wenxu, Suwon-si (KR); Yeon-hee Kim, Seoul (KR); Jung-hyun Lee, Suwon-si (KR)

(73) Assignee: Samsung Electronics Co., Ltd., Suwon-si (KR)

(21) Appl. No.: 12/926,125

(22) Filed: Oct. 27, 2010

(30) Foreign Application Priority Data
Jan. 6, 2010 (KR) 10-2010-0000902

(51) Int. Cl. H01L 31/0256; H01L 31/18; H01L 31/0224; B82Y 30/00

(52) U.S. Cl. 136/255; 438/57; 257/E31.001; 977/762

(57) ABSTRACT

Solar cells and methods of manufacturing the same, the solar cells include a plurality of nanowire heterostructures, wherein each of the plurality of nanowire heterostructures includes a nanowire including at least one p-type nanowire layer and at least one n-type nanowire layer, and a semiconductor material layer disposed on the nanowire. The semiconductor material layer constitutes a p-n junction with the p-type or n-type nanowire layer. The semiconductor material layer includes at least one of the p-type material layer and the n-type material layer.

### CROSS-REFERENCE TO RELATED APPLICATIONS

This application claims priority under 35 U.S.C. §119 from Korean Patent Application No. 10-2010-0000902, filed on Jan. 6, 2010, in the Korean Intellectual Property Office, the disclosure of which is incorporated herein by reference in its entirety.

### BACKGROUND

1. Field

Example embodiments relate to solar cells, and more particularly, to solar cells using nanowires and methods of manufacturing the same.

2. Description of the Related Art

Solar cells are conducive for suppressing environmental contamination, as well as, a solution to energy-related problems. Thus, there has been a considerable amount of research on low-priced solar cells with high efficiency. In the field of solar cells, bulk type crystalline silicon (Si) solar cells account for a majority of the solar cells, but bulk type crystalline silicon solar cells have low efficiency. Thus, the development of high-efficiency solar cells is necessary.

Si nanowires, which may be manufactured by deposition, may efficiently absorb light in a wide band. When Si nanowires are applied to solar cells, electron-hole pairs may be efficiently collected. Thus, the efficiency of the solar cells may be improved. Such Si nanowires have been manufactured by a high-temperature vapor-liquid-solid (VLS) method or by wet etching bulk type Si. However, it is difficult to manufacture low-priced Si nanowires using the high-temperature VLS method or by wet etching bulk type Si.

### SUMMARY

Provided are solar cells using nanowires and methods of manufacturing the same.

Additional aspects will be set forth in part in the description which follows and, in part, will be apparent from the description, or may be learned by practice of the presented example embodiments.

According to example embodiments, a solar cell includes a plurality of nanowire heterostructures, wherein each of the plurality of nanowire heterostructures includes a nanowire including at least one p-type nanowire layer and at least one n-type nanowire layer, and a semiconductor material layer disposed on the nanowire. The semiconductor material layer constitutes (or forms) a p-n junction with the p-type or n-type nanowire layer. The semiconductor material layer includes at least, one of a p-type material layer and an n-type material layer.

The p-type and n-type nanowire layers may be disposed along an axial direction of the nanowire, and at least one of the p-type and n-type material layers that constitutes the semiconductor material layer may be disposed along a radial direction of the nanowire.

The semiconductor material layer may be over (or on) the p-type or n-type nanowire layer disposed in an uppermost portion of the nanowire.

The nanowire may further include at least one i-type nanowire layer, and the semiconductor material layer may further include at least one i-type material layer.

Each of the nanowire heterostructures may include silicon (Si), silicon carbide (SiC), germanium (Ge), silicon germanium (SiGe), a compound semiconductor or combinations thereof.

According to example embodiments, a solar cell includes a first electrode, a plurality of nanowires arranged on the first electrode, wherein each of the plurality of nanowires includes at least one p-type nanowire layer and at least one n-type nanowire layer, a semiconductor material layer disposed on the nanowires, and at least one second electrode disposed on the semiconductor material layer. The semiconductor material layer constitutes a p-n junction with the at least one p-type or n-type nanowire layer. The semiconductor material layer includes at least one of a p-type material layer and an n-type material layer.

A transparent conductive material layer may be formed between the semiconductor material layer and the at least one second electrode to cover the semiconductor material layer.

The first electrode may include a transparent conductive material, and the second electrode may include at least one metal.

The semiconductor material layer may surround (or enclose) the p-type or n-type nanowire layer disposed on an uppermost portion of each of the nanowires.

The semiconductor material layer may have a greater thickness than that of the p-type or n-type nanowire layer disposed on the uppermost portion of each of the nanowires and may bury (or enclose) the uppermost portion of each of the nanowires.

The solar cell may further include a burying layer formed between the first electrode and the semiconductor material layer. The burying layer buries (or enclose) a lower portion that is under the uppermost portion of each of the nanowires.

According to example embodiments, a method of manufacturing a solar cell is provided, the method includes disposing a first electrode on a substrate, forming a template layer through which a plurality of nano-sized pores are formed on the first electrode, growing a plurality of nanowires on the first electrode exposed through each of the pores, forming a semiconductor material layer on the template layer to cover the nanowires, forming a transparent conductive material layer to cover the semiconductor material layer, and forming at least one second electrode on the transparent conductive material layer. The plurality of nanowires each include at least one p-type nanowire layer and at least one n-type nanowire layer. The semiconductor material layer includes at least one of a p-type material layer and an n-type material layer.

The method may further include, after the template layer is formed, forming a metal catalyst layer on the first electrode exposed through each of the pores. The metal catalyst layer may be formed through a reduction process using plasma-enhanced chemical vapor deposition (PECVD) equipment.

The nanowires and the semiconductor material layer may be formed through PECVD.

### BRIEF DESCRIPTION OF THE DRAWINGS

These and/or other aspects will become apparent and more readily appreciated from the following description of the embodiments, taken in conjunction with the accompanying drawings of which:

FIG. 1 is a schematic cross-sectional view of a solar cell according to example embodiments;

FIG. 2 is a cross-sectional view of one of a plurality of nanowire heterostructures of the solar cell of FIG. 1;

FIG. 3 is a schematic cross-sectional view of a solar cell according to example embodiments;

FIG. 4 is a cross-sectional view of one of a plurality of nanowire heterostructures of the solar cell of FIG. 3;

FIGS. 5 through 9 are cross-sectional views illustrating a method of manufacturing the solar cell of FIG. 1 according to example embodiments; and

FIGS. 10 through 13 are cross-sectional views illustrating a method of manufacturing the solar cell of FIG. 3 according to example embodiments.

### DETAILED DESCRIPTION

Various example embodiments will now be described more fully with reference to the accompanying drawings in which some example embodiments are shown. However, specific structural and functional details disclosed herein are merely representative for purposes of describing example embodiments. Thus, the invention may be embodied in many alternate forms and should not be construed as limited to only example embodiments set forth herein. Therefore, it should be understood that there is no intent to limit example embodiments to the particular forms disclosed, but on the contrary, example embodiments are to cover all modifications, equivalents, and alternatives falling within the scope of the invention.

In the drawings, the thicknesses of layers and regions may be exaggerated for clarity, and like numbers refer to like elements throughout the description of the figures.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that, if an element is referred to as being “connected” or “coupled” to another element, it can be directly connected, or coupled, to the other element or intervening elements may be present. In contrast, if an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” if used herein, specify the presence of stated features, integers, steps, operations, elements and/or components, but do not preclude the presence or addition of one or more other features, integers, steps, operations, elements, components and/or groups thereof.

Spatially relative terms (e.g., “beneath,” “below,” “lower,” “above,” “upper” and the like) may be used herein for ease of description to describe one element or a relationship between a feature and another element or feature as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

In order to more specifically describe example embodiments, various aspects will be described in detail with reference to the attached drawings. However, the present invention is not limited to example embodiments described.

Example embodiments relate to solar cells, and more particularly, to solar cells using nanowires and methods of manufacturing the same.

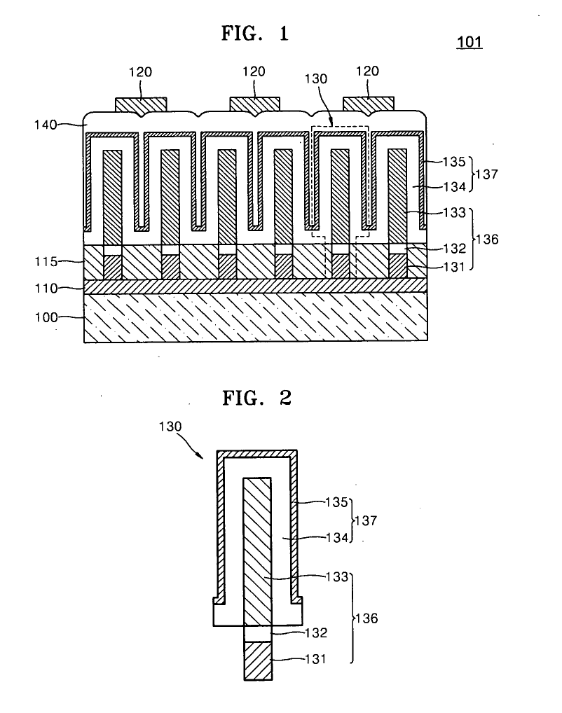

FIG. 1 is a schematic cross-sectional view of a solar cell according to example embodiments, and FIG. 2 is a cross-sectional view of one of a plurality of nanowire heterostructures of the solar cell of FIG. 1.

Referring to FIGS. 1 and 2, a solar cell 101 includes a first electrode 110, a plurality of nanowire heterostructures 130 disposed on the first electrode 110, and at least one second electrode 120 disposed on the nanowire heterostructures 130. Each of the nanowire heterostructures 130 includes a nanowire 136 and a semiconductor material layer 137 disposed on the nanowire 136. Each nanowire 136 has a heterostructure according to an axial direction of the nanowire 136, and the nanowire 136 and the semiconductor material layer 137 have a heterostructure according to a radial direction of the nanowire 136.

The first electrode 110 may be disposed on a substrate 100. The substrate 100 may, for example, be formed of silicon (Si), glass, stainless steel, plastic or the like. The substrate 100 may also be formed of other materials than the above materials. The first electrode 110 may be formed of a transparent conductive material. For example, the first electrode 110 may be formed of the transparent conductive material (e.g., fluorine doped tin oxide (FTO), aluminum doped zinc oxide (AZO), indium tin oxide (ITO) or the like). The material for forming the first electrode 110 is not limited thereto.

The nanowire 136 is disposed on the first electrode 110. The nanowire 136 may be arranged on the first electrode 110 to be perpendicular to the first electrode 110 or to be inclined at an angle. The nanowire 136 may have a structure in which first, second and third nanowire layers 131, 132 and 133 are sequentially stacked. In detail, the first, second and third nanowire layers 131, 132 and 133 may be sequentially disposed along the axial direction of the nanowire 136. The first nanowire layer 131 may be a p-type nanowire layer doped with a p-type semiconductor material, for example. The second nanowire layer 132 may, for example, be an i-type nanowire layer formed of an i-type semiconductor material. The third nanowire layers 133 disposed on an uppermost portion of the nanowire 136 may be n-type nanowire layers formed of an n-type semiconductor material. For example, each of the first, second and third nanowire layers 131, 132 and 133 may include p-type Si, Si and n-type Si. The nanowire 136 may include an IV-group semiconductor (e.g., silicon carbide (SiC), germanium (Ge), silicon germanium (SiGe) or the like), as well as, Si. The nanowire 136 may also include a compound semiconductor (e.g., an III-V-group semiconductor, an II-VI-group semiconductor or the like). Although the first and third nanowire layers 131 and 133 are illustrated as the p-type nanowire layer and the n-type nanowire layer, respectively, the first and third nanowire layers 131 and 133 may be the n-type nanowire layer and the p-type nanowire layer, respectively.

As described, the nanowire 136 has a p-i-n junction structure. However, example embodiments are not limited thereto. The nanowire 136 may have various junction structures. For example, the nanowire 136 may have a p-n junction structure. In this case, the nanowire 136 does not include the second nanowire layer 132 that is the i-type nanowire layer. The nanowire 136 may have a p-n-p, n-p-n, p-i-n-i-p or n-i-p-i-n junction structure and may also have other multi-junction structures than the p-n-p, n-p-n, p-i-n-i-p or n-i-p-i-n junction structure. In this case, the junction structure of the nanowire 136 may be designed so that a band gap structure may be optimized.

A burying layer 115 is formed on the first electrode 110 to bury (or enclose) a lower portion of the nanowire 136. Referring to FIG. 1, the burying layer 115 may be formed to bury the first and second nanowire layers 131 and 132. As such, the third nanowire layers 133 disposed on the uppermost portion of the nanowire 136 are exposed outside of the burying layer 115. The burying layer 115 may be formed of anodic aluminum oxide (AAO), for example. However, example embodiments are not limited thereto.

The semiconductor material layer 137 is disposed on the burying layer 115 to cover each of the third nanowire layers 133. The semiconductor material layer 137 may include a first material layer 134 for surrounding the third nanowire layers 133 and a second material layer 135 formed on the first material layer 134. In detail, the first and second material layers 134 and 135 may be sequentially disposed along the radial direction of the nanowire 136. When the third nanowire layers 133 are n-type nanowire layers, for example, each of the first and second material layers 134 and 135 may be the i-type material layer and the p-type material layer, respectively. For example, the third nanowire layers 133, and the first and second material layers 134 and 135 may include n-type Si, Si, and p-type Si, respectively. In this case, the third nanowire layers 133 and the semiconductor material layer 137 may constitute an n-i-p junction structure. The third nanowire layers 133 and the semiconductor material layer 137 may have various junction structures, as described above with respect to the nanowire 136. For example, the third nanowire layers 133 and the semiconductor material layer 137 may have the p-n, p-n-p, n-p-n, p-i-n-i-p or n-i-p-i-n junction structure and may also have other multi-junction structures than the p-n, p-n-p, n-p-n, p-i-n-i-p or n-i-p-i-n junction structure. The third nanowire layers 133 and the semiconductor material layer 137 may have a junction structure corresponding to the junction structure of the nanowire 136.

The semiconductor material layer 137 may include the IV-group semiconductor (e.g., Si, SiC, Ge, SiGe or the like), similar to the nanowire 136. The semiconductor material layer 137 may also include the compound semiconductor (e.g., the III-V-group semiconductor, the II-VI-group semiconductor or the like).

A transparent conductive material layer 140 may be formed on the semiconductor material layer 137. The transparent conductive material layer 140 may be formed on the second material layer 135 to fill a space between the nanowires 136. The transparent conductive material layer 140 may be formed of FTO, AZO, ITO or the like, for example. However, example embodiments are not limited thereto. A plurality of second electrodes 120 are disposed on the transparent conductive material layer 140. The second electrodes 120 may be formed of a metal having excellent electrical conductivity, for example. In FIGS. 1 and 2, the plurality of second electrodes 120 are disposed on the transparent conductive material layer 140. Alternatively, only one second electrode 120 may be disposed on the transparent conductive material layer 140.

The solar cell illustrated in FIGS. 1 and 2 includes the nanowire heterostructures 130 each having a heterostructure according to the axial direction of the nanowire 136 and a heterostructure according to the radial direction of the nanowire 136 so that efficiency of the solar cell may increase.

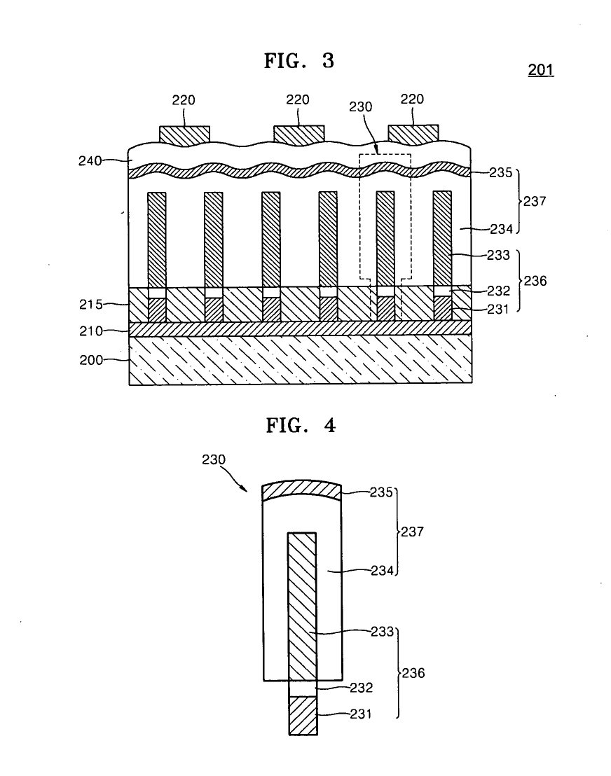

FIG. 3 is a schematic cross-sectional view of a solar cell according to example embodiments, and FIG. 4 is a cross-sectional view of one of a plurality of nanowire heterostructures of the solar cell of FIG. 3. Hereinafter, differences between FIGS. 1 and 2 and FIGS. 3 and 4 will be described.

Referring to FIGS. 3 and 4, a solar cell 201 includes a first electrode 210, a plurality of nanowire heterostructures 230 disposed on the first electrode 210, and at least one second electrode 220 disposed on the nanowire heterostructures 230. Each of the nanowire heterostructures 230 includes a nanowire 236 and a semiconductor material layer 237 disposed on the nanowire 236.

The first electrode 210 may be disposed on a substrate 200. The first electrode 210 may be formed of a transparent conductive material (e.g., FTO, AZO, ITO or the like), for example. However, the material for forming the first electrode 210 is not limited thereto. The nanowire 236 is disposed on the first electrode 210. The nanowire 236 may have a structure in which first, second and third nanowire layers 231, 232 and 233 are sequentially stacked. The first, second and third nanowire layers 231, 232 and 233 may be sequentially disposed along the axial direction of the nanowire 236. The first, second and third nanowire layers 231, 232 and 233 may, for example, be a p-type nanowire layer, an i-type nanowire layer and an n-type nanowire layer, respectively.

The nanowire 236 may, for example, include an IV-group semiconductor (e.g., Si, SiC, Ge, SiGe or the like). The nanowire 236 may also include a compound semiconductor (e.g., an III-V-group semiconductor, an II-VI-group semiconductor or the like). Although the first and third nanowire layers 231 and 233 are illustrated as the p-type nanowire layer and the n-type nanowire layer, each of the first and third nanowire layers 231 and 233 may be the n-type nanowire layer and the p-type nanowire layer, respectively.

As described, the nanowire 236 has a p-i-n junction structure. However, example embodiments are not limited thereto. The nanowire 236 may have various junction structures. For example, the nanowire 236 may have a p-n-p, n-p-n, p-i-n-i-p or n-i-p-i-n junction structure and may also have other multi-junction structures than the p-n-p, n-p-n, p-i-n-i-p or n-i-p-i-n junction structure.

A burying layer 215 is formed on the first electrode 210 to bury (or enclose) a lower portion of the nanowire 236. The burying layer 215 may be formed to bury the first and second nanowire layers 231 and 232. As such, the third nanowire layers 233 disposed on the uppermost portion of the nanowire 236 are exposed to the outside on the burying layer 215. The semiconductor material layer 237 is disposed on the burying layer 215 to cover each of the third nanowire layers 233. The semiconductor material layer 237 may include a first material layer 234 for burying the third nanowire layers 233 and a second material layer 235 formed on the first material layer 234.

The first material layer 234 has a greater thickness than that of the third nanowire layers 233 disposed on the uppermost portion of the nanowire 236 and thus buries the third nanowire layers 233. A second material layer 235 is formed on the first material layer 234.

When the third nanowire layers 233 are n-type nanowire layers, for example, each of the first and second material layers 234 and 235 may be the i-type material layer and the p-type material layer, respectively. In this case, the third nanowire layers 233 and the semiconductor material layer 237 constitute an n-i-p junction structure. However, the third nanowire layers 233 and the semiconductor material layer 237 may have various junction structures, similar to the above-described nanowire 236. For example, the third nanowire layers 233 and the semiconductor material layer 237 may have the p-n, p-n-p, n-p-n, p-i-n-i-p or n-i-p-i-n junction structure and may also have other multi-junction structures than the p-n, p-n-p, n-p-n, p-i-n-i-p or n-i-p-i-n junction structure. The third nanowire layers 233 and the semiconductor material layer 237 may have a junction structure corresponding to the junction structure of the nanowire 236. The semiconductor material layer 237 may include the IV-group semiconductor (e.g., Si, SiC, Ge, SiGe or the like), similar to the nanowire 236. The semiconductor material layer 237 may also include the compound semiconductor (e.g., the III-V-group semiconductor, the II-VI-group semiconductor or the like).

A transparent conductive material layer 240 may be formed on the semiconductor material layer 237. The transparent conductive material layer 240 may be formed of FTO, AZO, ITO or the like, for example. However, example embodiments are not limited thereto.

A plurality of second electrodes 220 are disposed on the transparent conductive material layer 240. The second electrodes 220 may be formed of a metal having excellent electrical conductivity, for example. In FIGS. 3 and 4, the plurality of second electrodes 220 are disposed on the transparent conductive material layer 240. Alternatively, only one second electrode 220 may be disposed on the transparent conductive material layer 240.

Hereinafter, a method of manufacturing the solar cell of FIG. 1 and a method of manufacturing the solar cell of FIG. 3 will be described.

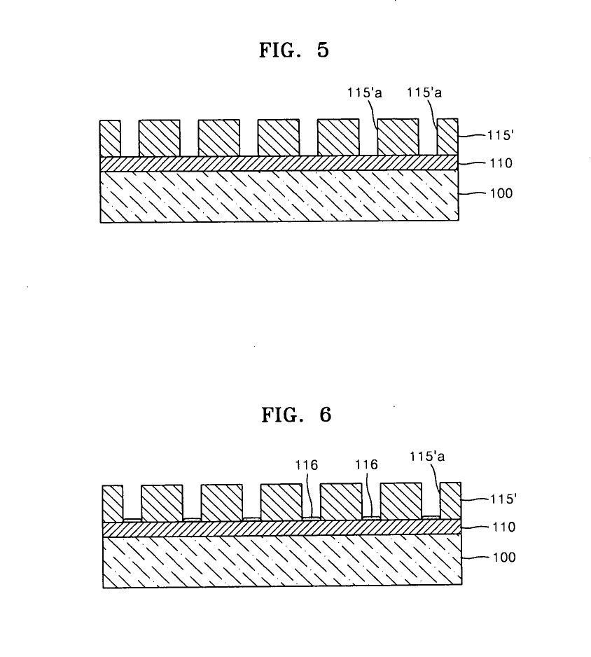

FIGS. 5 through 9 are cross-sectional views illustrating a method of manufacturing the solar cell of FIG. 1 according to example embodiments.

Referring to FIG. 5, the substrate 100 is prepared, and then the first electrode 110 is disposed on the substrate 100. The substrate 100 may be formed of Si, glass, stainless steel, plastic or the like, for example. However, the material for forming the substrate 100 is not limited thereto. The first electrode 110 may be formed by depositing a transparent conductive material (e.g., FTO, AZO, ITO or the like), for example, on the substrate 100. Subsequently, a template layer 115′, through which a plurality of nano-sized pores 115′a are formed, is formed on the first electrode 110. The template layer 115′ may be formed of anode aluminum oxide (AAO) or the like, for example. However, the material for forming the template layer 115′ is not limited thereto.

Referring to FIG. 6, a metal catalyst layer 116 is formed on the first electrode 110 that is exposed through each of the pores 115′a. The metal catalyst layer 116 may be formed by reducing the surface of the first electrode 110 and by depositing a metal by using plasma-enhanced chemical vapor deposition (PECVD) equipment. Gas that is used in a PECVD process may include H₂, for example. The metal catalyst layer 116 is used to grow the nanowire 136 that will be described later. The metal catalyst layer 116 may include tin (Sn), indium (In), aluminum (Al), gallium (Ga) or the like. However, the material for forming the metal catalyst layer 116 is not limited thereto.

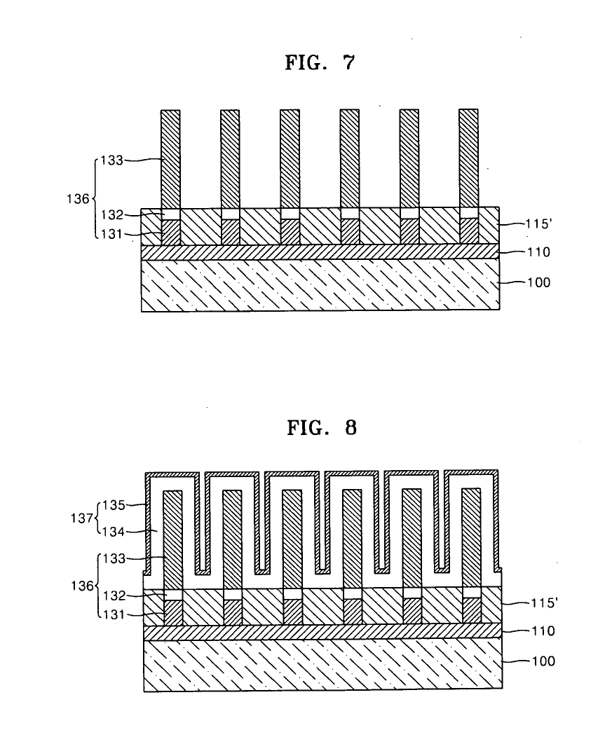

Referring to FIG. 7, the nanowire 136 is grown from the metal catalyst layer 116. Growth of the nanowire 136 may be performed through the PECVD process. Gas that is used in the PECVD process may include a mixed gas of SiH₄ and argon (Ar), helium (He) or H₂. The nanowire 136 may be arranged to be perpendicular to the first electrode 110 or to be inclined at an angle. The nanowire 136 may be formed by sequentially depositing the first, second and third nanowire layers 131, 132 and 133. In detail, the first, second and third nanowire layers 131, 132 and 133 may be sequentially formed along the axial direction of the nanowire 136. The first and second nanowire layers 131 and 132 are buried by the template layer 115′, and the third nanowire layers 133 disposed on the uppermost portion of the nanowire 136 are exposed to the outside on the template layer 115′.

Each of the first, second and third nanowire layers 131, 132 and 133 may be the p-type nanowire layer, the i-type nanowire layer and the n-type nanowire layer, respectively. For example, the first, second and third nanowire layers 131, 132 and 133 may include p-type Si, Si and n-type Si, respectively. The nanowire 136 may include a IV-group semiconductor (e.g., SiC, Ge, SiGe or the like). The nanowire 136 may also include a compound semiconductor (e.g., a III-V-group semiconductor, a II-VI-group semiconductor or the like). Although the first and third nanowire layers 131 and 133 are illustrated as the p-type nanowire layer and the n-type nanowire layer, each of the first and third nanowire layers 131 and 133 may be the n-type nanowire layer and the p-type nanowire layer, respectively.

As described, the nanowire 136 has the p-i-n junction structure. However, example embodiments are not limited thereto, and the nanowire 136 may have various junction structures. For example, the nanowire 136 may have a p-n junction structure. In this case, the nanowire 136 does not include the second nanowire layer 132 that is the i-type nanowire layer. The nanowire 136 may have a p-n-p, n-p-n, and p-i-n-i-p or n-i-p-i-n junction structure and may also have other multi-junction structures than the p-n-p, n-p-n, p-i-n-i-p or n-i-p-i-n junction structure. After the nanowire 136 is formed, catalyst particles (not shown) that constitute the metal catalyst layer 116 may remain on a top surface of the nanowire 136. The catalyst particles may be removed by wet etching. The catalyst particles may not be removed but may remain on the top surface of the nanowire 136.

Referring to FIG. 8, the semiconductor material layer 137 is formed to cover the third nanowire layers 133 exposed to the outside. The semiconductor material layer 137 may be formed through the PECVD process, similar to the formation of the above-described nanowire 136. Gas that is used in the PECVD process may include the mixed gas of SiH₄ and Ar, He or H₂. The semiconductor material layer 137 may include the first material layer 134 for surrounding the third nanowire layers 133 and the second material layer 135 formed on the first material layer 134. In other words, the first and second material layers 134 and 135 may be sequentially formed along the radial direction of the nanowire 136.

When the third nanowire layers 133 are the n-type nanowire layers, for example, each of the first and second material layers 134 and 135 may be the i-type material layer and the p-type material layer. In this case, the third nanowire layers 133 and the semiconductor material layer 137 may constitute the n-i-p junction structure. The third nanowire layers 133 and the semiconductor material layer 137 may have various junction structures like the above-described nanowire 136. For example, the third nanowire layers 133 and the semiconductor material layer 137 may have the p-n, p-n-p, n-p-n, p-i-n-i-p or n-i-p-i-n junction structure and may also have other multi-junction structures than the p-n, p-n-p, n-p-n, p-i-n-i-p or n-i-p-i-n junction structure. The third nanowire layers 133 and the semiconductor material layer 137 may have a junction structure corresponding to the junction structure of the nanowire 136.

The semiconductor material layer 137 may include a IV-group semiconductor (e.g., Si, SiC, Ge, SiGe or the like), similar to the nanowire 136, and may also include a compound semiconductor (e.g., a III-V-group semiconductor, a II-VI-group semiconductor or the like).

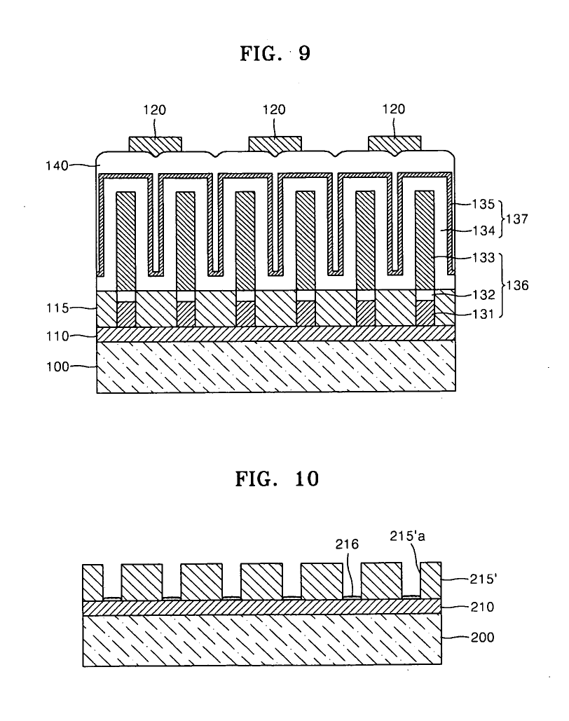

Referring to FIG. 9, the transparent conductive material layer 140 is formed to cover the semiconductor material layer 137. The transparent conductive material layer 140 may be formed by depositing a transparent conductive material (e.g., FTO, AZO, ITO or the like) on the second material layer 135 to fill a space between the nanowires 136. Subsequently, the plurality of second electrodes 120 are disposed on the transparent conductive material layer 140. The second electrodes 120 may be formed of at least one metal having excellent electrical conductivity, for example. Alternatively, one second electrode 120 may also be disposed on the transparent conductive material layer 140.

When the nanowire 136 and the semiconductor material layer 137 are formed through the PECVD process, the nanowire 136 and the semiconductor material layer 137 may be formed at a lower temperature at a high speed so that a low-priced solar cell may be manufactured.

FIGS. 10 through 13 are cross-sectional views illustrating a method of manufacturing the solar cell of FIG. 3 according to example embodiments. Hereinafter, differences between FIGS. 5 through 9 and FIGS. 10 through 13 will be described.

Referring to FIG. 10, the substrate 200 is prepared, and then the first electrode 210 is formed on the substrate 200. Subsequently, a template layer 215′, through which a plurality of nano-sized pores 215′a are formed, is formed on the first electrode 210. A metal catalyst layer 216 is formed on the first electrode 210 that is exposed through each of the pores 215′a. The metal catalyst layer 216 may be formed through a reduction process using PECVD equipment. The metal catalyst layer 216 may include Sn, In, Al, Ga or the like. However, the material for forming the metal catalyst layer 216 is not limited thereto.

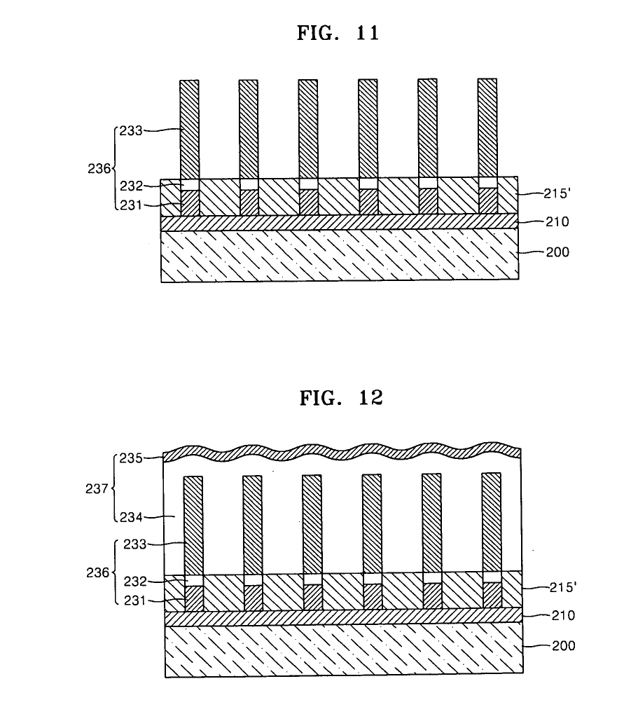

Referring to FIG. 11, the nanowire 236 is grown from the metal catalyst layer 216. Growth of the nanowire 236 may be performed through the PECVD process. The nanowire 236 may be formed by sequentially depositing the first, second and third nanowire layers 231, 232 and 233. Here, the first and second nanowire layers 231 and 232 are buried by the template layer 215′, and the third nanowire layers 233 disposed on the uppermost portion of the nanowire 236 are exposed to the outside on the template layer 215′.

Each of the first, second and third nanowire layers 231, 232 and 233 may be the p-type nanowire layer, the i-type nanowire layer and the n-type nanowire layer, respectively. The nanowire 236 may include a IV-group semiconductor (e.g., SiC, Ge, SiGe or the like), and may also include a compound semiconductor (e.g., a III-V-group semiconductor, a II-VI-group semiconductor or the like).

The nanowire 236 is illustrated with a p-i-n junction structure. However, example embodiments are not limited thereto, and the nanowire 236 may have various junction structures. For example, the nanowire 236 may have the p-n junction structure. In this case, the nanowire 236 does not include the second nanowire layer 232 that is the i-type nanowire layer. The nanowire 236 may have a p-n-p, n-p-n, p-i-n-i-p or n-i-p-i-n junction structure, and may also have other multi-junction structures than the p-n-p, n-p-n, p-i-n-i-p or n-i-p-i-n junction structure.

Referring to FIG. 12, the semiconductor material layer 237 is formed to cover the third nanowire layers 233 exposed to the outside. The semiconductor material layer 237 may be formed through the PECVD process. The semiconductor material layer 237 may include the first material layer 234 for surrounding the third nanowire layers 233 and the second material layer 235 formed on the first material layer 234. The first material layer 234 is deposited on the surface of the third nanowire layers 233 disposed on the uppermost portion of the nanowire 236. Here, the first material layer 234 has a greater thickness than that of the third nanowire layers 233 and thus buries the third nanowire layers 233. The second material layer 235 is formed on the first material layer 234.

When the third nanowire layers 233 are the n-type nanowire layers, for example, each of the first and second material layers 234 and 235 may be the i-type material layer and the p-type material layer, respectively. In this case, the third nanowire layers 233 and the semiconductor material layer 237 may constitute the n-i-p junction structure. However, the third nanowire layers 233 and the semiconductor material layer 237 may have various junction structures like the above-described nanowire 236. The semiconductor material layer 237 may include a IV-group semiconductor (e.g., Si, SiC, Ge, SiGe or the like), similar to the nanowire and may also include a compound semiconductor (e.g., a III-V-group semiconductor, a II-VI-group semiconductor or the like).

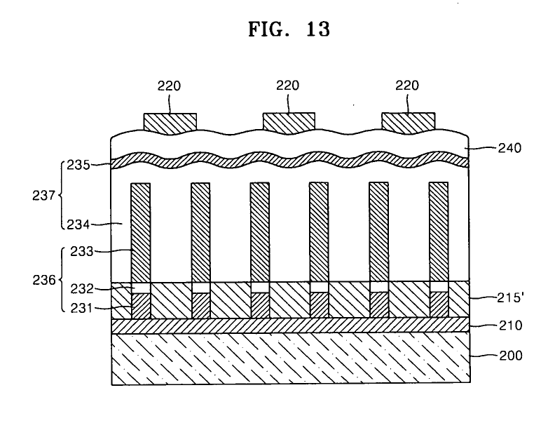

Referring to FIG. 13, the transparent conductive material layer 240 is formed to cover the semiconductor material layer 237. The transparent conductive material layer 240 may be formed by depositing a transparent conductive material (e.g., FTO, AZO, ITO or the like) on the second material layer 235. Subsequently, the plurality of second electrodes 220 are disposed on the transparent conductive material layer 240. The second electrodes 220 may be formed of at least one metal having excellent electrical conductivity, for example. Alternatively, one second electrode 220 may also be disposed on the transparent conductive material layer 140.

As described above, a solar cell according to example embodiments includes a plurality of nanowire heterostructures each having an axial heterostructure and a radial heterostructure so that efficiency of the solar cell may increase. Because the nanostructure may be formed through PECVD at a lower temperature at a high speed, a low-priced solar cell may be manufactured.

It should be understood that the exemplary embodiments described therein should be considered in a descriptive sense only and not for purposes of limitation. Descriptions of features or aspects within each embodiment should typically be considered as available for other similar features or aspects in other embodiments.

What is claimed is:

1. A solar cell, comprising:
a plurality of nanowire heterostructures, wherein each of the plurality of nanowire heterostructures includes,
a nanowire including at least one p-type nanowire layer and at least one n-type nanowire layer, and
a semiconductor material layer disposed on the nanowire, wherein the semiconductor material layer includes at least one of a p-type material layer and an n-type material layer, and forms a p-n junction with the p-type or n-type nanowire layer.

2. The solar cell of claim 1, wherein the p-type and n-type nanowire layers are along an axial direction of the nanowire, and at least one of the p-type and n-type material layers is along a radial direction of the nanowire.

3. The solar cell of claim 1, wherein the semiconductor material layer is on the p-type or n-type nanowire layer in an uppermost portion of the nanowire.

4. The solar cell of claim 1, wherein the nanowire further includes at least one i-type nanowire layer, and the semiconductor material layer further includes at least one i-type material layer.

5. The solar cell of claim 1, wherein each of the nanowire heterostructures includes silicon (Si), silicon carbide (SiC), germanium (Ge), silicon germanium (SiGe) or a compound semiconductor.

6. The solar cell of claim 1, further comprising:
a first electrode, wherein the plurality of nanowires heterostructures are on the first electrode; and
at least one second electrode on the semiconductor material layer.

7. The solar cell of claim 6, further comprising a transparent conductive material layer between the semiconductor material layer and the at least one second electrode, the transparent conductive material layer covering the semiconductor material layer.

8. The solar cell of claim 6, wherein the nanowire further includes at least one i-type nanowire layer, and the semiconductor material layer further includes at least one i-type material layer.

9. The solar cell of claim 6, further comprising a substrate on which the first electrode is disposed.

10. The solar cell of claim 6, wherein the first electrode includes a transparent conductive material, and the second electrode includes at least one metal.

11. The solar cell of claim 6, wherein the nanowire is aligned on the first electrode to be perpendicular to the first electrode or to be inclined at an angle.

12. The solar cell of claim 6, wherein the at least one p-type nanowire layer and the at least one n-type nanowire layer are along the axial direction of the nanowires.

13. The solar cell of claim 12, wherein the semiconductor material layer surrounds the p-type or n-type nanowire layer on an uppermost portion of the nanowire.

14. The solar cell of claim 13, further comprising a burying layer between the first electrode and the semiconductor material layer, the burying layer burying a lower portion that is under the uppermost portion of the nanowire.

15. The solar cell of claim 12, wherein the semiconductor material layer has a greater thickness than that of the p-type or n-type nanowire layer on an uppermost portion of the nanowire and buries the uppermost portion of the nanowire.

16. The solar cell of claim 15, further comprising a burying layer between the first electrode and the semiconductor material layer, the burying layer burying a lower portion that is under the uppermost portion of the nanowire.

17. The solar cell of claim 6, wherein the nanowires and the semiconductor material layer include silicon (Si), silicon carbide (SiC), germanium (Ge), silicon germanium (SiGe), a compound semiconductor or combinations thereof.

18. A method of manufacturing a solar cell, the method comprising:
disposing a first electrode on a substrate;
forming a template layer on the first electrode, the template layer having a plurality of nano-sized pores, wherein the first electrode is exposed through the nano-sized pores;
growing a plurality of nanowires on the first electrode exposed through each of the nano-sized pores, the plurality of nanowires each including at least one p-type nanowire layer and at least one n-type nanowire layer;
forming a semiconductor material layer on the template layer to cover the plurality of nanowires, the semiconductor material layer including at least one of a p-type material layer and an n-type material layer;
forming a transparent conductive material layer to cover the semiconductor material layer; and
forming at least one second electrode on the transparent conductive material layer.

19. The method of claim 18, further comprising forming a metal catalyst layer on the first electrode exposed through each of the nano-sized pores, after forming the template layer and prior to growing the plurality of nanowires.

20. The method of claim 18, wherein the metal catalyst layer is formed through a reduction process using plasma-enhanced chemical vapor deposition (PECVD) equipment.

21. The method of claim 18, wherein the plurality of nanowires and the semiconductor material layer are formed through PECVD.

22. The method of claim 18, wherein each of the nanowires further includes at least one i-type nanowire layer, and the semiconductor material layer further includes at least one i-type material layer.

23. The method of claim 18, wherein the plurality of nanowires and the semiconductor material layer include silicon (Si), silicon carbide (SiC), germanium (Ge), silicon germanium (SiGe), a compound semiconductor or combinations thereof.

24. The method of claim 18, wherein the semiconductor material layer surrounds the p-type or n-type nanowire layer on an uppermost portion of each of the nanowires.

25. The method of claim 18, wherein the semiconductor material layer has a greater thickness than that of the p-type or n-type nanowire layer on an uppermost portion of each of the nanowires and buries the uppermost portion of each of the nanowires.

26. The method of claim 18, wherein the first electrode includes a transparent conductive material, and the second electrode includes at least one metal.
